(19) United States
(12) Patent Application Publication
(10) Pub. No.: US 2020/0373373 A1
(43) Pub. Date: Nov. 26, 2020

(54) DISPLAY SUBSTRATE, METHOD FOR MANUFACTURING THE SAME, AND DISPLAY DEVICE

(71) Applicant: BOE Technology Group Co., Ltd., Beijing (CN)

(72) Inventors: Ziyu Zhang, Beijing (CN); Song Zhang, Beijing (CN); Weifeng Zhou, Beijing (CN)

(21) Appl. No.: 16/766,310

(22) PCT Filed: Oct. 29, 2019
(86) PCT No.: PCT/CN2019/113888

§ 371 Date: May 22, 2020

(30) Foreign Application Priority Data
Oct. 30, 2018 (CN) 201811275484.5

(51) Int. Cl. H01L 27/32; H01L 51/52; H01L 51/56

(52) U.S. Cl. CPC H01L 27/3276; H01L 2227/323; H01L 51/56; H01L 51/5253

(57) ABSTRACT

Disclosed is a display substrate including a base substrate, and a power signal line and an electrode block that are disposed on the base substrate, the electrode block covering at least one side of the power signal line. The base substrate has an encapsulation area. An orthographic projection of the power signal line on the base substrate extends out of the encapsulation area from an interior of the encapsulation area, and an orthographic projection of the electrode block on the base substrate overlaps the encapsulation area. By covering a side of the power signal line in the encapsulation area with the electrode block, the present disclosure can prevent the side of the power signal line covered with the electrode block from being drill-etched, thereby improving the encapsulation reliability of the display substrate.

### CROSS-REFERENCE TO RELATED APPLICATION

The present disclosure is a 371 of PCT/CN2019/113888, filed on Oct. 29, 2019, which claims priority to Chinese Patent Application No. 201811275484.5, filed on Oct. 30, 2018 and entitled “DISPLAY SUBSTRATE, MANUFACTURING METHOD THEREOF AND DISPLAY DEVICE”, the entire contents of which are incorporated herein by reference.

### TECHNICAL FIELD

The present disclosure relates to the field of display technologies, and more particularly to a display substrate, a method for manufacturing the same, and a display device.

### BACKGROUND

At present, flexible display devices are usually encapsulated in a manner of thin film encapsulation (TFE). The operation principle of TFE is that a dense TFE layer is adopted to block water and oxygen (hereinafter referred to as water oxygen for short), so that sensitive materials in the flexible display devices, such as metal materials and light emitting materials, can be prevented from being eroded by the water oxygen.

### SUMMARY

The present disclosure provides a display substrate, a method for manufacturing the same, and a display device. The technical solutions are as follows:

In one aspect, a display substrate is provided. The display substrate includes:

a base substrate, and a power signal line and an electrode block that are located on the base substrate, the electrode block covering at least one side of the power signal line; wherein

the base substrate has an encapsulation area; an orthographic projection of the power signal line on the base substrate extends out of the encapsulation area from an interior of the encapsulation area, and an orthographic projection of the electrode block on the base substrate overlaps the encapsulation area.

Optionally, the electrode block covers two sides of the power signal line.

Optionally, the electrode block includes a first portion, a second portion, a third portion, a fourth portion, and a fifth portion that are consecutively adjacent to each other, wherein both the first portion and the fifth portion are located on the base substrate, the second portion and the fourth portion are respectively attached to a lateral side of the power signal line, and the third portion covers a side of the power signal line away from the base substrate.

Optionally, a distance to the power signal line from an end of the first portion away from the power signal line is 2 to 20 microns, and a distance to the power signal line from an end of the fifth portion away from the power signal line is 2 to 20 microns.

Optionally, the orthographic projection of the electrode block on the base substrate completely covers the orthographic projection of the power signal line on the base substrate.

Optionally, the electrode block covers a side of the power signal line, and two sides of the power signal line are covered with one electrode block respectively.

Optionally, the electrode block has a shape of “Z”, and the electrode block includes a sixth portion, a seventh portion, and an eighth portion that are consecutively adjacent to each other, wherein the sixth portion overlaps the surface of the power signal line away from the base substrate, the seventh portion is attached to a target side of the power signal line, and the eighth portion is located on the base substrate, the target side being one of two sides of the power signal line.

Optionally, a distance to the target side from an end of the sixth portion away from the target side is 2 to 20 microns, and a distance to the target side from an end of the eighth portion away from the target side is 2 to 20 microns.

Optionally, the display substrate further includes a thin film transistor located on the base substrate, wherein the power signal line and a source/drain pattern of the thin film transistor are made of a same material and disposed on a same layer.

Optionally, the display substrate further includes a light emitting device disposed on a side of the thin film transistor away from the base substrate, wherein the light emitting device includes a first electrode, a light emitting layer, and a second electrode that are laminated in a direction away from the base substrate, and the electrode block and the first electrode are made of a same material and disposed on a same layer.

Optionally, the display substrate further includes a first power signal line and a second power signal line that are insulated from each other; wherein

the first power signal line is connected to the first electrode, and the second power signal line is connected to the second electrode.

Optionally, the power signal line includes a first metal layer, a second metal layer, and a third metal layer that are laminated in a direction away from the base substrate, wherein the second metal layer is made of a material different from that of the first metal layer and that of the third metal layer.

Optionally, the second metal layer has a greater metal activity than the first metal layer and the third metal layer.

Optionally, the thin film transistor is one of a thin film transistor having a top gate structure and a thin film transistor having a bottom gate structure.

Optionally, the display substrate further includes: a thin film transistor disposed on the base substrate, wherein the power signal line and a source/drain pattern of the thin film transistor are made of a same material and are disposed on a same layer;

the display substrate further includes a light emitting device disposed on a side of the thin film transistor away from the base substrate, wherein the light emitting device includes a first electrode, a light emitting layer, and a second electrode that are laminated in a direction away from the base substrate, and the electrode block and the first electrode are made of a same material and are disposed on a same layer; and

the power signal line includes a first metal layer, a second metal layer, and a third metal layer that are laminated in a direction away from the base substrate, wherein the second metal layer has a greater metal activity than the first metal layer and the third metal layer.

In another aspect, a display device is provided. The display device includes any one of the display substrates according to one aspect.

In yet another aspect, a method of manufacturing a display substrate is provided. The method includes:

providing a base substrate that has an encapsulation area;

forming a power signal line on the base substrate, an orthographic projection of the power signal line on the base substrate extending out of the encapsulation area from an interior of the encapsulation area; and

forming an electrode block on the base substrate on which the power signal line is formed, the electrode block covering at least one side of the power signal line, and an orthographic projection of the electrode block on the base substrate overlapping the encapsulation area.

Optionally, forming the electrode block on the base substrate on which the power signal line is formed includes:

forming the electrode block and a first electrode of a light emitting device on a same layer of the base substrate on which the power signal line is formed.

Optionally, after forming the electrode block and the first electrode of the light emitting device on the same layer of the base substrate on which the power signal line is formed, the method further includes:

forming a light emitting layer on the base substrate on which the first electrode is formed; and

forming a second electrode of the light emitting device on a base substrate on which the light emitting layer is formed.

Optionally, forming the electrode block and the first electrode of the light emitting device on the same layer of the base substrate on which the power signal line is formed includes:

forming a metal layer on the base substrate on which the power signal line is formed;

coating a photoresist on a side of the metal layer away from the base substrate, and sequentially performing an exposure process and a development process on the photoresist;

etching the metal layer through a wet etching process; and

stripping the photoresist to obtain the first electrode and the electrode block.

### BRIEF DESCRIPTION OF THE DRAWINGS

FIG. 1 is a top structural view of a flexible display device in the related art;

FIG. 2 is a schematic sectional view of the flexible display device shown in FIG. 1 taken at an AA′ position;

FIG. 3 is a schematic sectional view of the flexible display device shown in FIG. 1 taken at a BB′ position;

FIG. 4 is a top structural view of a display substrate according to an embodiment of the present disclosure;

FIG. 5 is a schematic sectional view of the display substrate illustrated in FIG. 4 taken at a CC′ position;

FIG. 6 is a schematic sectional view of the display substrate illustrated in FIG. 4 taken at a DD′ position;

FIG. 7 is a schematic structural view of an electrode block according to an embodiment of the present disclosure;

FIG. 8 is a schematic structural view of another electrode block according to an embodiment of the present disclosure;

FIG. 9 is a flowchart of a method of manufacturing a display substrate according to an embodiment of the present disclosure;

FIG. 10 is a flowchart of another method of manufacturing a display substrate according to an embodiment of the present disclosure; and

FIG. 11 is a flowchart of a method according to an embodiment of the present disclosure, in which an electrode block and a first electrode of a light emitting device on the same layer on a base substrate on which a power signal line is formed.

### DETAILED DESCRIPTION

The present disclosure will be described in further detail with reference to the accompanying drawings, to present the objects, technical solutions, and advantages of the present disclosure more clearly.

Current flexible display devices typically include: a base substrate, and a thin film transistor (TFT), a light emitting device, and a thin film encapsulation (abbreviated as TFE) layer that are sequentially disposed on the base substrate in a direction away from the base substrate. The TFT includes a gate pattern, a gate insulating layer, an active layer, and a source/drain pattern that are provided in a laminated manner. The source/drain pattern includes a source electrode and a drain electrode arranged in the display area, and a power signal line arranged in the non-display area. That is, the power signal line is manufactured on the same layer as the source and drain electrodes. The light emitting device includes an anode, a light emitting layer, and a cathode that are laminated in sequence in a direction away from the base substrate.

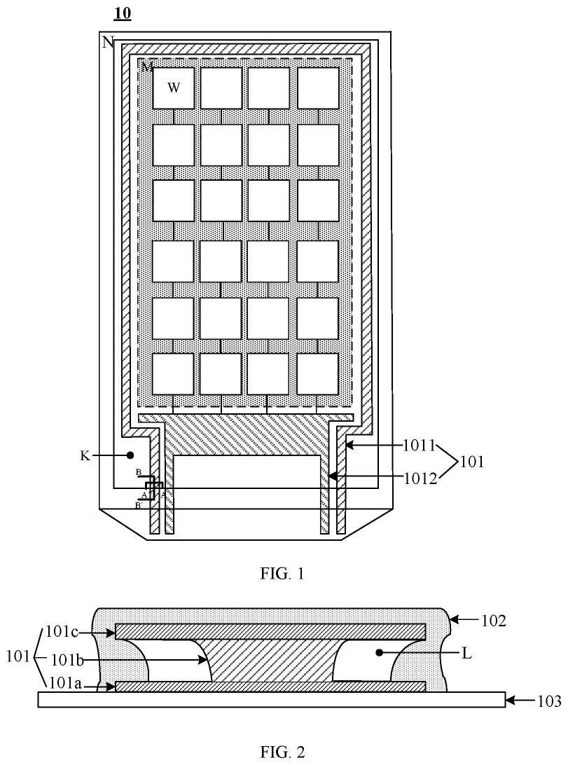

FIG. 1 is a top view of a structure of a flexible display device in the related art. As shown in FIG. 1, the flexible display device 10 has a display area M (the area inside the dashed block) and a non-display area N (the area outside the dashed block). A plurality of sub-pixels W are arranged in array in the display area M, and the power signal line 101 is disposed in the non-display area N. An area where the TFE layer (not indicated in the figure) is disposed in the encapsulation area K of the flexible display device. The display area M is arranged in the encapsulation area K, and edges of the encapsulation area K are in the non-display area N. The power signal line 101 disposed in the non-display area N extends from the interior of the encapsulation area K to the outside of the encapsulation area K so as to be connected to an external control circuit (not shown in the figure). The external control circuit provides a power signal to the cathode and/or the anode (not shown in the figure) of the light emitting device through the power signal line 101. Referring to FIG. 1, the power signal line 101 includes a first power signal line 1011 and a second power signal line 1012. The first power signal line 1011 and the second power signal line 1012 are one of a VDD signal line and a VSS signal line, respectively.

FIG. 2 is a schematic sectional view of the flexible display device shown in FIG. 1 taken at an AA′ position. As shown in FIG. 2, the power signal line 101 is composed of a first metal layer 101a, a second metal layer 101b, and a third metal layer 101c that are laminated in a direction away from the base substrate 103. The second metal layer has a greater activity (also known as metal activity) than the first metal layer and the third metal layer. While manufacturing the source/drain pattern, metal material with high activity is generally adopted as the conductive material to ensure the good conductivity of the source electrode, the drain electrode, and the power signal line. For example, the metal aluminum is adopted as the material for manufacturing the source/drain pattern. However, since the metal material with high activity is prone to be oxidized, the metal material with low activity is usually adopted to protect the metal material with high activity, so as to prevent the metal material with high activity from being oxidized which influences its conductivity. For example, a metal titanium is adopted on the upper and lower surfaces of the metal aluminum layer respectively to form protective layers. Therefore, the current source/drain pattern usually has a three-layer structure.

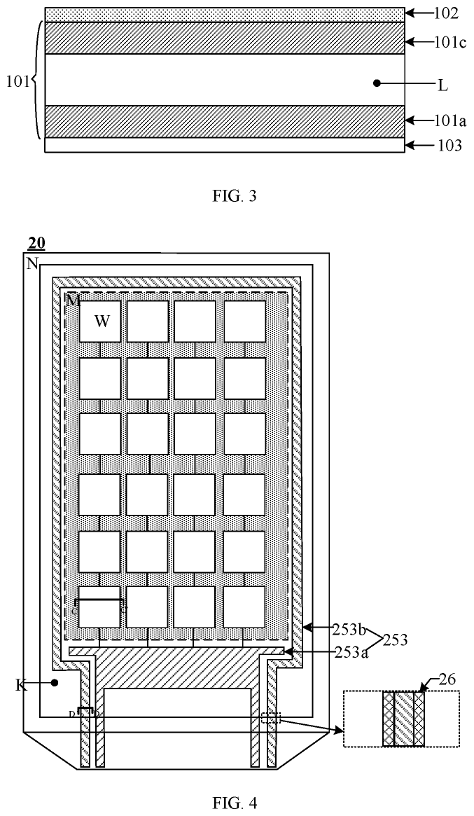

During the process of manufacturing the flexible display device shown in FIG. 1, when the anode (not shown in the figure) of the light emitting device is manufactured through a wet etching process, the etching speed of the second metal layer by the etching liquid is higher than that of the first metal layer and the third metal layer since the second metal layer in the power signal line has a greater activity than the first metal layer and the third metal layer, which may thereby cause the power signal line to be drill-etched. Drill-etching refers to lateral etching under the lithographic mask. As shown in FIG. 2, a slit L is formed inside the power signal line 101 that is drill-etched. While performing the TFE after manufacturing the light emitting device, the TFE layer 102 may fail to completely fill the slit L formed inside the power signal line 101. FIG. 3 is a schematic sectional view of the flexible display device shown in FIG. 1 taken at a BB′ position. As shown in FIG. 3, the slit L formed inside the power signal line 101 may become a path for water oxygen to penetrate, such that the external water oxygen enters the display area of the flexible display device through the slit L, which may cause erosion to the light emitting device, and thereby affect the light emitting performance of the light emitting device. Therefore, the encapsulation reliability of the flexible display device is rather low currently.

FIG. 4 is a top structural view of a display substrate according to an embodiment of the present disclosure. As illustrated in FIG. 4, the display substrate 20 has a display area M (the area inside the dashed block) and a non-display area N located around the display area M. The display area M is provided with a plurality of sub-pixels W arranged in array.

FIG. 5 is a schematic sectional view of the display substrate illustrated in FIG. 4 taken at a CC′ position. As illustrated in FIG. 5, the display substrate 20 includes a base substrate 201, and a thin film transistor 202, a light emitting device 203, and an encapsulation structure 204 that are sequentially disposed on the base substrate 201 in a direction away from the base substrate 201. The TFT includes a gate pattern, a gate insulating layer, an active layer, and a source/drain pattern.

Optionally, the TFT is a TFT with a top gate structure or a TFT with a bottom gate structure.

Exemplarily, FIG. 5 illustrates the thin film transistor having the top gate structure as an example. Referring to FIG. 5, the thin film transistor 202 includes an active layer 21, a first gate insulating layer 22, a gate pattern 23, a second gate insulating layer 24, and a source/drain pattern 25 that are laminated in sequence in a direction away from the substrate 201. The source/drain pattern 25 includes a source electrode 251 and a drain electrode 252 disposed in the display area. Optionally, a barrier layer, a buffer layer, and the like (not shown in the figure) which are provided in a laminated manner are further disposed between the base substrate 201 and the active layer 21.

Optionally, the TFT having the bottom gate structure includes a gate pattern, a gate insulating layer, an active layer, and a source/drain pattern that are laminated in a direction away from the base substrate, which will not be elaborated in the embodiment of the present disclosure.

Optionally, further referring to FIG. 5, the light emitting device 203 includes a first electrode 31, a light emitting layer 32, and a second electrode 33 that are laminated in a direction away from the base substrate 201. The light emitting layer includes a first carrier injecting layer, a first carrier transporting layer, a light emitting material layer, a second carrier transporting layer, and a second carrier injecting layer that are provided in a laminated manner. When the first carrier is a hole and the second carrier is an electron, the first electrode is an anode and the second electrode is a cathode. When the first carrier is the electron and the second carrier is the hole, the first electrode is a cathode and the second electrode is an anode. Optionally, the first carrier injecting layer, the first carrier transporting layer, the second carrier transporting layer, and the second carrier injecting layer are all of a whole-layer structure. Thus, during the process of manufacturing the display substrate, the first carrier injecting layer, the first carrier transporting layer, the second carrier transporting layer, and the second carrier injecting layer may be manufactured as a whole layer to simplify the manufacturing process of the light emitting device.

Optionally, the light emitting device may be a quantum dot light emitting diode (QLED) device or an organic light emitting diode (OLED) device, which is not limited in the embodiment of the present disclosure.

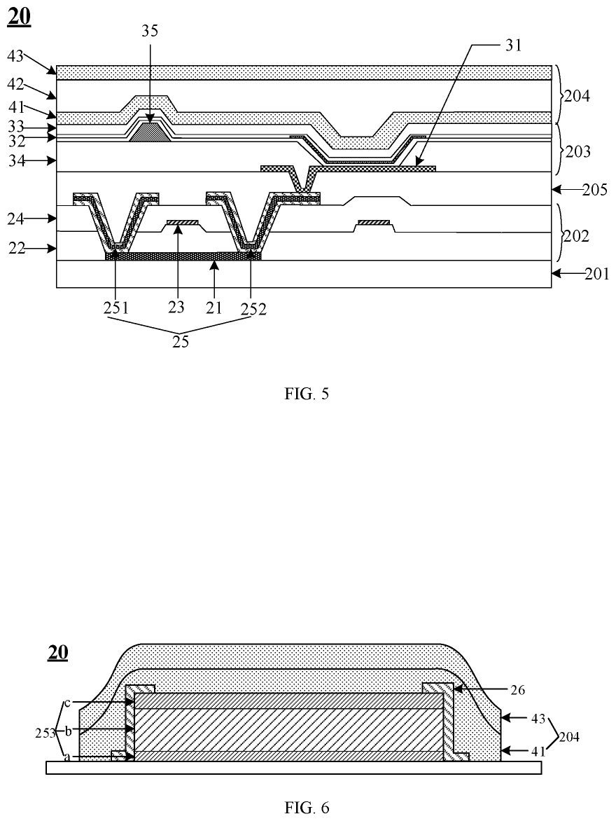

FIG. 6 is a schematic sectional view of the display substrate illustrated in FIG. 4 at a DD′ position. As illustrated in FIG. 6, the display substrate 20 includes a base substrate 201, and a power signal line 253 and an electrode block 26 that are disposed on the base substrate 201. The electrode block 26 covers at least one side of the power signal line. That the electrode block covers at least one side of the power signal line means that the electrode block covers at least one side surface of the power signal line. The side surface of the power signal line is parallel to the extending direction of the power signal line and has an included angle that is not zero with the base substrate. In the embodiment of the present disclosure, the side surface of the power signal line and the side of the power signal line may refer to an end surface of the power signal line close to the encapsulation structure.

Please referring to FIG. 4 again, the base substrate includes an encapsulation area K. The display area M is located in the encapsulation area K where the encapsulation structure is located, and an edge of the encapsulation area K is located in the non-display area N. The orthographic projection of the power signal line 253 on the base substrate extends out of the encapsulation area K from the interior of the encapsulation area K, and the power signal line 253 is usually disposed in the non-display area N. The orthographic projection of the electrode block 26 on the base substrate has an overlapping area with the encapsulation area K. The encapsulation area of the base substrate is an encapsulation area of the display substrate. An encapsulation area on the base substrate 201 in FIG. 6 is an orthographic projection area of the encapsulation structure 204 on the base substrate 201.

Optionally, the power signal line and the source/drain pattern of the TFT are formed on the same layer. That is, the power signal line is disposed on the same layer and made of the same material as the source/drain pattern of the thin film transistor.

Optionally, please refer to FIG. 4 again, the display substrate 20 includes a first power signal line 253a and a second power signal line 253b (collectively referred to as the power signal line 253) that are insulated from each other. The first power signal line 253a is electrically connected to the first electrode of the light emitting device, and the second power signal line 253b is electrically connected to the second electrode of the light emitting device.

Optionally, the electrode block 26 and the first electrode 31 of the light emitting device are manufactured on the same layer. That is, the electrode block 26 is located on the same layer and made of the same material as the first electrode 31 of the light emitting device. Thus, there is no necessity to add a new process to manufacture the electrode block, which thereby has high implementability.

Optionally, when the first electrode is an anode and the second electrode is a cathode, the first power signal line is a VDD signal line, and the second power signal line is a VSS signal line; whereas when the first electrode is a cathode and the second electrode is an anode, the first power signal line is the VSS signal line, and the second power signal line is the VDD signal line. The second electrode may be provided as a whole layer, and the first electrode is electrically connected to the first power signal line through the TFT. The TFT is configured to control a voltage loaded on the first electrode.

Optionally, the width of the power signal line ranges from 50 microns to 2000 microns.

In summary, in the display substrate according to the embodiments of the present disclosure, the electrode block covers at least one side of the power signal line, and the orthographic projection of the electrode block on the base substrate overlaps the encapsulation area. Thus, while manufacturing the electrode of the light emitting device through the wet etching process, the side of the power signal line covered with the electrode block can be prevented from being drill-etched. After providing the encapsulation area on a side of the light emitting device away from the substrate, a path for water oxygen to penetrate may not be formed on the side of the power signal line covered with the electrode block, which can suppress the penetration of water oxygen to a certain extent, thereby improving the encapsulation reliability of the display substrate.

Optionally, please refer to FIG. 6 again, the power signal line includes a first metal layer a, a second metal layer b, and a third metal layer c that are laminated in a direction away from the substrate. That is, the power signal line is of a three-layer structure. The second metal layer is made of a material different from the first metal layer and the third metal layer. Optionally, the second metal layer has a metal activity greater than that of the first metal layer and that of the third metal layer.

Optionally, the encapsulation structure provided by the embodiment of the present disclosure may be composed of an organic encapsulation layer and an inorganic encapsulation layer that are provided in a laminated manner. Exemplarily, as illustrated in FIG. 5, the encapsulation structure 204 may include a first inorganic encapsulation layer 41, an organic encapsulation layer 42, and a second inorganic encapsulation layer 43 that are disposed in a laminated manner.

It should be noted that the first inorganic encapsulation layer and the second inorganic encapsulation layer may serve to block the water oxygen, and the organic encapsulation layer may serve to planarize the area and release stresses. The organic encapsulation layer is usually disposed in the display area. The orthographic projection of the inorganic encapsulation layer (i.e., the second inorganic encapsulation layer 43 in FIG. 5) disposed on a side of the organic encapsulation layer away from the base substrate, on the organic encapsulation layer completely covers the organic encapsulation layer, so as to prevent the external water oxygen from penetrating into the light emitting device through the organic encapsulation layer.

Exemplarily, referring to FIG. 6, the first inorganic encapsulation layer 41 and the second inorganic encapsulation layer 43 of the encapsulation structure 204 cover the power signal line 253 disposed in the encapsulation area. Both the first inorganic encapsulation layer and the second inorganic encapsulation layer are configured to encapsulate the display area, and both the first inorganic encapsulation layer and the second inorganic encapsulation layer both extend from the display area to the non-display area. Thus, when the first inorganic encapsulation layer and the second inorganic encapsulation layer that are located in the non-display area can form a sealing ring, the display area can be hermetically encapsulated.

Optionally, as illustrated in FIG. 5, the display substrate 20 further includes a planarization layer 205 between the TFT 202 and the light emitting device 203. The flattening layer may be formed of an organic insulating material.

It should be noted that forming the planarization layer on a side of the TFT away from the substrate can provide a planar manufacturing environment for manufacturing the light emitting device and isolate interference caused by the electric signal in the thin film transistor on the light emitting device, thereby improving the manufacturing yield of the light emitting device.

Optionally, please refer to FIG. 5 again, the light emitting device 203 further includes a pixel defining layer 34. The pixel defining layer 34 is disposed between the first electrode 31 and the light emitting layer 32.

Optionally, please refer to FIG. 5 again, the light emitting device 203 further includes a spacer pillar 35. The spacer pillar 35 is disposed on a side of the pixel defining layer 34 away from the base substrate 201.

It should be noted that the pixel defining layer is configured to define a contact area between the light emitting layer and the first electrode, that is, to define an actual light emitting area of the pixel. The layers of the light emitting device are usually manufactured through an evaporation process. The spacer pillar is configured to support a fine metal mask (FMM) during evaporating material of the film layers through the FMM, so as to ensure the manufacturing reliability.

Optionally, in the embodiment of the present disclosure, a side of the power signal line is covered with the electrode block; or, two sides of the power signal line are both covered with the electrode block. The embodiment of the present disclosure is illustrated by taking an example in which two sides of the power signal line of the display substrate are both covered with the electrode block.

It should be noted that, when two sides of the power signal line are both covered with the electrode block, a slit caused by drill-etching may no more occur in the power signal line, that is, no path for water oxygen to penetrate will exist in the power signal line. Thus, after providing the encapsulation structure on a side of the light emitting device away from the base substrate, the encapsulation structure can hermetically encapsulate the light emitting device, which further improves the encapsulation reliability of the display substrate.

Optionally, the electrode block provided in the embodiment of the present disclosure may have various structures, and the following two structures are taken as examples for illustration.

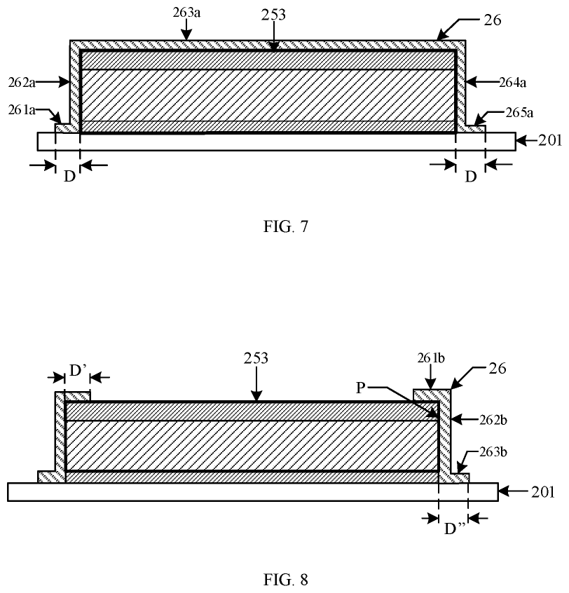

A structure of a first type of electrode block is illustrated in FIG. 7. The electrode block 26 covers two sides of the power signal line 253. That is, the electrode block 26 that covers two sides of the power signal line 253 has an integrated structure.

Exemplarily, referring to FIG. 7, the electrode block 26 includes a first portion 261a, a second portion 262a, a third portion 263a, a fourth portion 264a, and a fifth portion 265a that are consecutively adjacent to each other. The first portion 261a and the fifth portion 265a are both disposed on the base substrate 201. The second portion 262a and the fourth portion 264a are attached at a side of the power signal line 253, respectively. The third portion 263a covers a side surface of the power signal line 253 away from the base substrate 201.

Optionally, a distance D to the power signal line 253 from an end of the first portion 261a away from the power signal line 253 is 2 to 20 microns. Optionally, a distance D to the power signal line 253 from an end of the fifth portion 265a away from the power signal line 253 is 2 to 20 microns.

It should be noted that the electrode block having the integrated structure covers the upper surface and lateral side surface of the power signal line, which can prevent the power signal line from being drill-etched, thereby preventing slits from being generated in the power signal line. Thus, after providing the encapsulation structure on a side of the light emitting device away from the base substrate, the encapsulation structure can hermetically encapsulate the light emitting device and block the path for the water oxygen to penetrate, which thereby improves the encapsulation reliability of the display substrate. Furthermore, the electrode block having the integrated structure may cover two sides of the power signal line at the same time. Thus, the manufacturing process is simple, and the implementability is high.

Optionally, the orthographic projection of the electrode block 26 in FIG. 7 on the base substrate 201 completely covers the orthographic projection of the power signal line 253 on the base substrate 201. That is, the electrode block 26 may be connected in parallel with the power signal line 253 to reduce the resistance of the power signal line to a certain extent.

A structure of a second type of electrode block is illustrated in FIG. 8. The electrode block 26 covers a side of the power signal line 253, and two sides of the power signal line 253 are respectively covered with a electrode block 26. That is, two sides of the power signal line 253 are respectively covered with different electrode blocks 26. The orthographic projection of the electrode block 26 on the base substrate 201 partially overlaps the orthographic projection of the power signal line 253 on the base substrate 201.

Exemplarily, referring to FIG. 8, the electrode block 26 has a “Z” shape. The electrode block 26 includes a sixth portion 261b, a seventh portion 262b, and an eighth portion 263b that are consecutively adjacent to each other. The sixth portion 261b is overlapped on a surface of the power signal line 253 away from the base substrate 201. The seventh portion 262b is attached to a target side P of the power signal line 253. The target side P is one of two sides of the power signal line 253. The eighth portion is disposed on the base substrate 201.

Optionally, the distance D′ to the target side P from an end of the sixth portion 261b away from the target side P is 2 to 20 microns. The distance D′ to the target side P from an end of the eighth portion 263b away from the target side P is 2 to 20 microns.

It should be noted that the electrode block covers the side surface of the power signal line, so that the power signal line can be prevented from being drill-etched, thereby preventing slits from being generated in the power signal line. Thus, after providing the encapsulation structure on a side of the light emitting device away from the base substrate, the encapsulation structure can hermetically encapsulate the light emitting device and block the path for the water oxygen to penetrate, which thereby improves the encapsulation reliability of the display substrate.

In summary, in the display substrate according to the embodiments of the present disclosure, the electrode block covers at least one side of the power signal line, and the orthographic projection of the electrode block on the base substrate has an overlapping area with the encapsulation area. Thus, while manufacturing the electrode of the light emitting device through the wet etching process, the side of the power signal line covered with the electrode block can be prevented from being drill-etched. After providing the encapsulation area on a side of the light emitting device away from the substrate, the path for the water oxygen to penetrate may not be formed on the side surface of the power signal line covered with the electrode block, which can suppress the penetration of the water oxygen, and thereby improve the encapsulation reliability of the display substrate. When two sides of the power signal line are both covered with the electrode block, the slit may no more occur in the power signal line, and thereby no path for water oxygen to penetrate will exist in the power signal line. Thus, after providing the encapsulation structure on a side of the light emitting device away from the base substrate, the encapsulation structure can hermetically encapsulate the light emitting device, which further improves the encapsulation reliability of the display substrate.

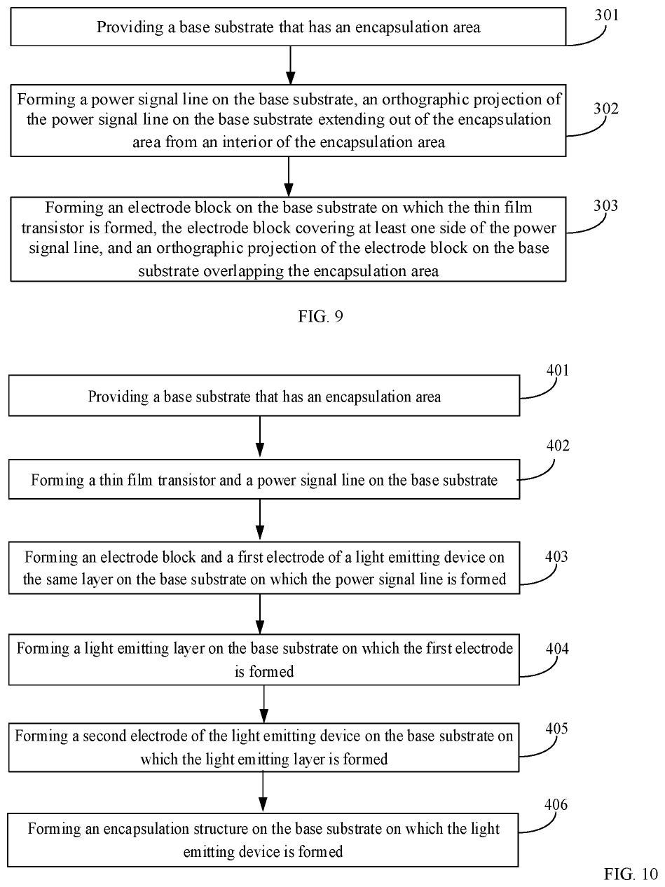

FIG. 9 is a flowchart of a method of manufacturing a display substrate according to an embodiment of the present disclosure. As illustrated in FIG. 9, the method may include following steps.

In step 301, a base substrate that has an encapsulation area is provided.

In step 302, a power signal line is formed on the base substrate, and an orthographic projection of the power signal line on the base substrate extends out of the encapsulation area from an interior of the encapsulation area.

In step 303, an electrode block is formed on the base substrate on which the TFT is formed. The electrode block covers at least one side of the power signal line, and an orthographic projection of the electrode block on the base substrate has an overlapping area with the encapsulation area.

After step 303, the aforesaid process further includes: forming a light emitting device on the base substrate on which the electrode block is formed.

In summary, in the method of manufacturing the display substrate according to the embodiments of the present disclosure, the electrode block is adopted to cover at least one side of the power signal line. Since the orthographic projection of the electrode block on the base substrate has an overlapping area with the encapsulation area, the side of the power signal line covered with the electrode block can be prevented from being drill-etched while manufacturing the electrode of the light emitting device through the wet etching process. After providing the encapsulation area on a side of the light emitting device away from the substrate, no path for the water oxygen to penetrate may be formed on the side of the power signal line covered with the electrode block, which can suppress the penetration of water oxygen to a certain extent, and thereby improve the encapsulation reliability of the display substrate.

FIG. 10 is a flowchart of another method of manufacturing a display substrate according to an embodiment of the present disclosure. As illustrated in FIG. 10, the method may include following steps.

In step 401, a base substrate that has an encapsulation area is provided.

Optionally, the base substrate may be a flexible base substrate. For example, the base substrate may be made of polyimide (PI). Alternatively, the base substrate may be a rigid base substrate. For example, the base substrate may be made of a material such as glass, silicon wafer, quartz, or plastic, which is not limited in the embodiments of the present disclosure.

In step 402, a TFT and a power signal line are formed on the base substrate.

Optionally, the power signal line and the source/drain pattern of the TFT are formed on the same layer. The source/drain pattern includes a source electrode and a drain electrode disposed in the display area, and the power signal line is typically located in the non-display area.

Optionally, the TFT may be a TFT with a top gate structure. The TFT includes a barrier layer, a buffer layer, an active layer, a first gate insulating layer, a gate pattern, a second gate insulating layer, and a source/drain pattern that are laminated in a direction away from the base substrate. Alternatively, the TFT may be a TFT with a bottom gate structure. The TFT includes a gate pattern, a gate insulating layer, an active layer, and a source/drain pattern that are laminated in a direction away from the base substrate. In the embodiment of the present disclosure, the TFT having the bottom gate structure is taken as an example to illustrate the manufacturing process of the TFT. The manufacturing process is as follows:

Optionally, the gate pattern may be made of metal molybdenum (Mo). Thus, a metal molybdenum layer is formed on the base substrate through a deposition process and then is patterned through a patterning process so as to form the gate pattern. The gate insulating layer may be made of silicon dioxide (SiO₂), silicon nitride (SiN), or aluminum oxide (Al₂O₃). For example, a SiO₂ film layer is formed on the base substrate on which the gate pattern is formed, through a deposition process, then is patterned through a patterning process to form the gate insulating layer. The active layer may be made of indium gallium zinc oxide (IGZO), monocrystalline silicon (a-Si), low temperature poly-silicon (LTPS), or low temperature polycrystalline oxide (LTPO). For example, an IGZO layer on the base substrate on which the gate insulating layer is formed, through a deposition process, then is patterned through a patterning process to form the gate active layer. The source/drain pattern may be made of metal titanium and metal aluminum. Thus, a metal titanium layer, a metal aluminum layer, and a metal titanium layer may be sequentially formed on the base substrate on which the active layer is formed, through a deposition process, and then is patterned through a patterning process to form the source/drain pattern. The patterning process may include coating photoresist, exposure, development, etching, and photoresist stripping. The materials of the various layers of the TFT and the manufacturing processes for the various layer structures of the TFT are not limited in the embodiments of the present disclosure.

In step 403, the electrode block and the first electrode of the light emitting device are formed on the same layer of the base substrate on which the power signal line is formed.

The electrode block covers at least one side of the power signal line, and an orthographic projection of the electrode block on the base substrate overlaps the encapsulation area. The first electrode is disposed in the display area, and the electrode block is typically disposed in the non-display area. Exemplarily, referring to FIG. 7, the electrode block may cover two sides of the power signal line. Further exemplarily, referring to FIG. 8, an electrode block covers one side of the power signal line.

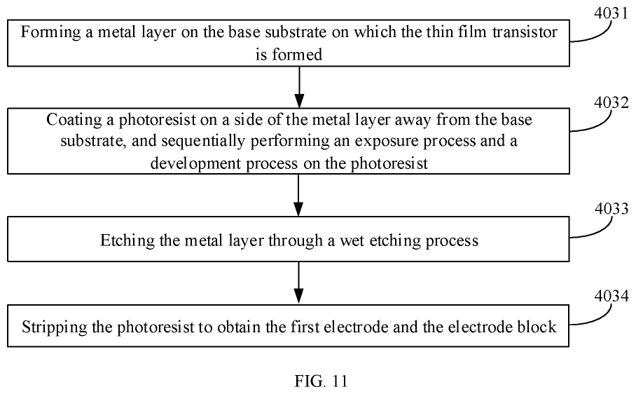

Optionally, FIG. 11 is a flowchart of a method of forming an electrode block and a first electrode of a light emitting device on the same layer of a base substrate on which a power signal line is formed according to an embodiment of the present disclosure. As illustrated in FIG. 11, the implementing process includes following steps.

In step 4031, a metal layer is formed on the base substrate on which the TFT is formed.

Optionally, the metal layer may be made of indium tin oxide (ITO), lithium fluoride, or aluminum. When the metal layer is made of ITO, the metal layer may be formed through depositing the ITO. When the metal layer is made of lithium fluoride or aluminum, the metal layer may be formed by evaporation. The material for the metal layer and the manufacturing process for the metal layer are not limited in the embodiments of the present disclosure.

In step 4032, a photoresist is coated on a side of the metal layer away from the base substrate, and an exposure process and a development process are sequentially performed on the photoresist.

Optionally, composition of the photoresist includes polymethyl methacrylate (PMMA), which is not limited in the embodiments of the present disclosure.

In step 4033, the metal layer is etched through a wet etching process.

Optionally, the wet etching refers to the etching performed under the chemical reaction between the etching liquid and the metal layer. The etching liquid may be hydrochloric acid (HCl), which is not limited in the embodiments of the present disclosure.

Alternatively, the metal layer may be etched through a dry etching process, which is not limited in the embodiments of the present disclosure.

In step 4034, the photoresist is stripped to obtain the first electrode and the electrode block.

Optionally, the photoresist can be stripped through a wet stripping process. The wet stripping refers to dissolving the photoresist through specific chemicals. Alternatively, the photoresist may be stripped through a dry stripping process. The dry stripping refers to striping the photoresist by ashing the photoresist through ashing components (such as, oxygen in a plasma state), which is not limited in the embodiments of the present disclosure.

In step 404, the light emitting layer is formed on the base substrate on which the first electrode is formed.

The light emitting layer includes a first carrier injecting layer, a first carrier transporting layer, a light emitting material layer, a second carrier transporting layer, and a second carrier injecting layer. The first carrier and the second carrier are one of an electron and a hole, respectively. Each of the first carrier injecting layer, the transporting layer, the second carrier transporting layer, and the second carrier injecting layer can be manufactured as a whole layer, so as to simplify the manufacturing process for the light emitting device.

Optionally, the hole injecting layer may be made of a thermoplastic polymer PEDOT: PSS (3,4-ethylenedioxythiophene/polystyrene sulfonate). The hole transporting layer may be made of 1,2,4,5-tetrakis (trifluoromethyl) benzene (TFB), and the hole injecting layer and hole transporting layer may be made of an inkjet printing process. The embodiments of the present disclosure do not limit the materials and the manufacturing processes for the hole injecting layer and hole transporting layer.

Optionally, the light emitting material layer may be a quantum dot material layer, so the flexible light emitting device is a QLED device. Alternatively, the light emitting material layer may be an organic light emitting material layer, so the flexible light emitting device is an OLED device. The light emitting material layer may be formed through a printing process. The embodiments of the present disclosure do not limit the material and the manufacturing process for the light emitting material layer.

Optionally, the electron transporting layer may be made of zinc oxide, and thereby may be formed through a printing or sputtering process. The electron injecting layer may be formed through a printing or sputtering process. The embodiments of the present disclosure do not limit the materials and the manufacturing processes for the electron transporting layer and the electron injecting layer.

In step 405, the second electrode of the light emitting device is formed on the base substrate on which the light emitting layer is formed.

Optionally, the second electrode may be made of ITO, lithium fluoride or aluminum. When the second electrode is made of ITO, a metal layer may be formed through depositing ITO. When the second electrode is made of lithium fluoride or aluminum, a metal layer may be formed through evaporation. The embodiments of the present disclosure do not limit the materials and the manufacturing processes for the second electrode. When the first carrier is the hole and the second carrier is the electron, the first electrode is an anode and the second electrode is a cathode. When the first carrier is the electron and the second carrier is the hole, the first electrode is a cathode and the second electrode is an anode.

In step 406, an encapsulation structure is formed on the base substrate on which the light emitting device is formed.

The orthographic projection of the encapsulation structure on the base substrate overlaps the encapsulation area of the base substrate. That is, the area where the encapsulation structure is located is the encapsulation area of the display substrate.

In the embodiment of the present disclosure, the orthographic projection of the electrode block on the base substrate overlaps the encapsulation area. Thus, even if an area of the power signal line not covered with the electrode block is drill-etched, the electrode block in the encapsulation area can ensure that the covered area is not drill-etched, which can block a path for water oxygen to penetrate in the power signal line. Therefore, after forming the encapsulation structure, the display area can be isolated from the outside environment to ensure the encapsulation reliability.

Optionally, the encapsulation structure according to the embodiments of the present disclosure may be constituted by an organic encapsulation layer and an inorganic encapsulation layer that are provided in a laminated manner. The organic encapsulation layer may be made of PMMA material, and may be thereby manufactured through an inkjet printing process. The inorganic encapsulation layer may be made of silicon oxide, silicon nitride, silicon oxynitride, or aluminum oxide, and may be thereby manufactured through a chemical vapor deposition (CVD) process or an atomic layer deposition (ALD) process. The organic encapsulation layer is typically located in the display area. The orthographic projection of the inorganic encapsulation layer on the organic encapsulation layer completely covers the organic encapsulation layer, and the first inorganic encapsulation layer and the second inorganic encapsulation layer both extend from the display area to the non-display area. Thus, when the first inorganic encapsulation layer and the second inorganic encapsulation layer that are located in the non-display area can form a sealing ring, the display area can be hermetically encapsulated.

It should be noted that the sequence of steps of the method of manufacturing the display substrate according to the embodiments of the present disclosure may be appropriately changed, and the steps may further be correspondingly added or deleted according to actual requirements. Any method that can be easily occurs to ordinary skill in the art within the technical scope disclosed in the present disclosure shall fall into the protection scope of the present disclosure, and therefore will not be elaborated.

In summary, in the method of manufacturing the display substrate according to the embodiment of the present disclosure, the electrode block covers at least one side of the power signal line. Since the orthographic projection of the electrode block on the base substrate overlaps the encapsulation area, the side of the power signal line covered with the electrode block can be prevented from being drill-etched while manufacturing the electrode of the light emitting device through the wet etching process. After providing the encapsulation area on a side of the light emitting device away from the substrate, the penetration of water oxygen can be suppressed to a certain extent, and thereby the encapsulation reliability of the display substrate can be improved. When two sides of the power signal line are both covered with the electrode block, the slit may no more occur in the power signal line, and thereby no path for water oxygen to penetrate will exist in the power signal line. Thus, after providing the encapsulation structure on a side of the light emitting device away from the base substrate, the encapsulation structure can hermetically encapsulate the light emitting device, which further improves the encapsulation reliability of the display substrate.

Regarding the structures mentioned in the method embodiments, structures and material of the display substrate have been described in detail in the device embodiments, and will not be elaborated herein.

An embodiment of the present disclosure further provides a display device, and the display device includes the display substrate as illustrated in any one of FIGS. 4 to 6.

Optionally, the display device according to the embodiments of the present disclosure may be any product or component having a display function, such as an electronic paper, a mobile phone, a tablet computer, a TV set, a display, a laptop computer, a digital photo frame, and a navigator etc.

The term “and/or” in the present disclosure merely describes the association relationship between the associated objects and indicates that there may be three relationships; for example, A and/or B may indicate three cases where only A exists, both A and B exist at the same time, and only B exists. The character “/” in the present disclosure generally indicates that the relationship between the former and later associated objects is “OR”.

The foregoing descriptions are merely optional embodiments of the present disclosure, and are not intended to limit the present disclosure. Within the spirit and principles of the disclosure, any modifications, equivalent substitutions, improvements, etc., are within the protection scope of the present disclosure.

What is claimed is:

1. A display substrate, comprising:
a base substrate, and a power signal line and an electrode block that are located on the base substrate, the electrode block covering at least one side of the power signal line; wherein
the base substrate has an encapsulation area; an orthographic projection of the power signal line on the base substrate extends out of the encapsulation area from an interior of the encapsulation area, and an orthographic projection of the electrode block on the base substrate overlaps the encapsulation area.

2. The display substrate according to claim 1, wherein the electrode block covers two sides of the power signal line.

3. The display substrate according to claim 2, wherein the electrode block comprises a first portion, a second portion, a third portion, a fourth portion, and a fifth portion that are consecutively adjacent to each other, wherein both the first portion and the fifth portion are disposed on the base substrate, the second portion and the fourth portion are respectively attached to a side of the power signal line, and the third portion covers a surface of the power signal line away from the base substrate.

4. The display substrate according to claim 3, wherein a distance to the power signal line from an end of the first portion away from the power signal line is 2 to 20 microns, and a distance to the power signal line from an end of the fifth portion away from the power signal line is 2 to 20 microns.

5. The display substrate according to claim 2, wherein the orthographic projection of the electrode block on the base substrate completely covers the orthographic projection of the power signal line on the base substrate.

6. The display substrate according to claim 1, wherein the electrode block covers a side of the power signal line, and two sides of the power signal line are respectively covered with one electrode block.

7. The display substrate according to claim 6, wherein the electrode block has a Z-shape, and the electrode block comprises a sixth portion, a seventh portion, and an eighth portion that are consecutively adjacent to each other, wherein the sixth portion is overlapped on a side of the power signal line away from the base substrate the seventh portion is attached to a target side of the power signal line, and the eighth portion is located on the base substrate, the target side being one of two sides of the power signal line.

8. The display substrate according to claim 7, wherein a distance to the target side from an end of the sixth portion away from the target side is 2 to 20 microns, and a distance to the target side from an end of the eighth portion away from the target side is 2 to 20 microns.

9. The display substrate according to claim 1, further comprising a thin film transistor located on the base substrate, wherein the power signal line and a source/drain pattern of the thin film transistor are made of a same material and disposed on a same layer.

10. The display substrate according to claim 9, further comprising a light emitting device located on a side of the thin film transistor away from the base substrate, wherein the light emitting device comprises a first electrode, a light emitting layer, and a second electrode that are laminated in a direction away from the base substrate, and the electrode block and the first electrode are made of a same material and disposed on a same layer.

11. The display substrate according to claim 10, further comprising a first power signal line and a second power signal line that are insulated from each other; wherein
the first power signal line is connected to the first electrode, and the second power signal line is connected to the second electrode.

12. The display substrate according to claim 1, wherein the power signal line comprises a first metal layer, a second metal layer, and a third metal layer that are laminated in a direction away from the base substrate, wherein the second metal layer is made of a material different from that of the first metal layer and that of the third metal layer.

13. The display substrate according to claim 12, wherein the second metal layer has a greater metal activity than the first metal layer and the third metal layer.

14. The display substrate according to claim 9, wherein the thin film transistor is one of a thin film transistor having a top gate structure and a thin film transistor having a bottom gate structure.

15. The display substrate according to claim 4, further comprising: a thin film transistor located on the base substrate, wherein the power signal line and a source/drain pattern of the thin film transistor are made of a same material and disposed on a same layer;
the display substrate further comprising a light emitting device disposed on a side of the thin film transistor away from the base substrate, wherein the light emitting device comprises a first electrode, a light emitting layer, and a second electrode that are laminated in a direction away from the base substrate, and the electrode block and the first electrode are made of a same material and disposed on a same layer; and
the power signal line comprises a first metal layer, a second metal layer, and a third metal layer that are laminated in a direction away from the base substrate, wherein the second metal layer has a greater metal activity than the first metal layer and the third metal layer.

16. A display device, comprising a display substrate, wherein the display substrate comprises:
a base substrate, and a power signal line and an electrode block that are located on the base substrate, the electrode block covering at least one side of the power signal line; wherein
the base substrate has an encapsulation area; an orthographic projection of the power signal line on the base substrate extends out of the encapsulation area from an interior of the encapsulation area, and an orthographic projection of the electrode block on the base substrate overlaps the encapsulation area.

17. A method of manufacturing a display substrate, comprising:
providing a base substrate that has an encapsulation area;
forming a power signal line on the base substrate, an orthographic projection of the power signal line on the base substrate extending out of the encapsulation area from an interior of the encapsulation area; and
forming an electrode block on the base substrate on which the power signal line is formed, the electrode block covering at least one side of the power signal line, and an orthographic projection of the electrode block on the base substrate overlapping the encapsulation area.

18. The method according to claim 17, wherein forming the electrode block on the base substrate on which the power signal line is formed comprises:
forming the electrode block and a first electrode of a light emitting device on a same layer of the base substrate on which the power signal line is formed.

19. The method according to claim 18, wherein after forming the electrode block and the first electrode of the light emitting device on the same layer of the base substrate on which the power signal line is formed, the method further comprises:
forming a light emitting layer on the base substrate on which the first electrode is formed; and
forming a second electrode of the light emitting device on the base substrate on which the light emitting layer is formed.

20. The method according to claim 18, wherein forming the electrode block and the first electrode of the light emitting device on the same layer of the base substrate on which the power signal line is formed comprises:
forming a metal layer on the base substrate on which the power signal line is formed;
coating a photoresist on a side of the metal layer away from the base substrate, and sequentially performing an exposure process and a development process on the photoresist;
etching the metal layer through a wet etching process; and
stripping the photoresist to obtain the first electrode and the electrode block.
